(19) United States
(12) Patent Application Publication
(10) Pub. No.: US 2025/0105218 A1
(43) Pub. Date: Mar. 27, 2025

(54) DISPLAY LIGHT ENGINE AND AUGMENTED REALITY DISPLAY

(71) Applicant: AUO Corporation, Hsinchu City (TW)

(72) Inventors: Chun-Hsiang Chan, Hsinchu City (TW); Ching-Liang Huang, Hsinchu City (TW); Ting-Wei Tsai, Hsinchu City (TW); Sheng-Ming Huang, Hsinchu City (TW)

(21) Appl. No.: 18/811,833

(22) Filed: Aug. 22, 2024

(30) Foreign Application Priority Data
Sep. 22, 2023 (TW) 112136378

(51) Int. Cl. H01L 25/075; H01L 33/10; H01L 33/50; H01L 33/58

(52) U.S. Cl. CPC H01L 25/0753; H10H 20/814; H10H 20/8512; H10H 20/855

(57) ABSTRACT

A display light engine which includes a light source module, a spectrum conversion array disposed on the light source module and a lens array is provided. The light source module includes a plurality of light-emitting components which emit light toward the spectrum conversion array. The spectrum conversion array includes a plurality of spectrum conversion components and a metal bank material. The spectrum conversion components are spaced from each other and are disposed on the light-emitting components respectively. The metal bank material is distributed between two adjacent spectrum conversion components and separates the spectrum conversion components from each other. The lens array which includes a plurality of lenses arranged in an array is disposed between the spectrum conversion array and the light source module. Those lenses are disposed on and align to the spectrum conversion components respectively.

### CROSS-REFERENCE TO RELATED APPLICATION

This application claims priority to Taiwan Application Serial Number 112136378, filed Sep. 22, 2023, which is herein incorporated by reference in its entirety.

### BACKGROUND

### Field of Invention

The present disclosure relates to a display light engine and an augmented reality display using the display light engine.

### Description of Related Art

In the field of head-mounted augmented reality display, the distance between the display panel and the wearer's eyes is extremely short. In order to display the image within the discernable range of the human eyes, the image on the display panel should be minified to a specific size, so that the image can be completely presented after entering the human eyes. However, in order to meet the demand for small scale images, the pixel size of the display panel and the pitch between adjacent pixels should also be reduced. When the pixel pitch is less than 5 μm, the sub-pixel pitch within each pixel is also reduced to less than 5 μm. Since the pitch between sub-pixels is extremely small, the light rays emitted by two adjacent sub-pixels are easily affected by each other, so as to cause optical cross-talk.

In recent, the impact of optical cross-talk is reduced by covering the pitch of sub-pixels by a black matrix. However, the light blocking of the black matrix is limited. Further, the black matrix absorbs a part of the light ray, so that the quantity of light of the display panel decreases.

### SUMMARY

At least one embodiment of the present disclosure provides a display light engine, which can help to reduce the optical cross-talk between the sub-pixels.

At least one embodiment of the present disclosure provides an augmented reality display using the aforementioned display light engine.

The display light engine according to at least one embodiment of the present disclosure includes a light source module, a spectrum conversion array and a lens array. The light source module includes a plurality of light-emitting components, and the plurality of light-emitting components are arranged in an array. The spectrum conversion array is disposed on the light source module, and the plurality of light-emitting components are configured to emit light toward the spectrum conversion array. The spectrum conversion array includes a plurality of spectrum conversion components spaced from each other, and the plurality of spectrum conversion components are disposed on and align to the plurality of light-emitting components. The spectrum conversion array includes a metal bank material distributed between two of the plurality of spectrum conversion components adjacent to each other and separating the plurality of spectrum conversion components from each other. The lens array is disposed between the spectrum conversion array and the light source module and including a plurality of lenses arranged in an array. The plurality of lenses are disposed on and align to the plurality of spectrum conversion components, respectively.

The augmented reality display according to at least another embodiment of the present disclosure includes the aforementioned display light engine and a light guide module. The display light engine is configured to emit an image light ray. The plurality of lens of the display light engine are configured to refract a light ray emitted by the plurality of light-emitting components aligning to the plurality of lens respectively, so that the light ray enters the plurality of spectrum conversion components align to the plurality of light-emitting components. The light guide module is configured to receive the image light ray emitted by the display light engine and to focus and transmit the image light ray toward wearer's eyes.

According to the at least one of aforementioned embodiments, the metal bank material is disposed between the spectrum conversion components. Since the metals included in the metal bank material are with high reflectivity to visible light, the light path of the light ray is restricted within the each spectrum conversion component. Therefore, the quantity of light of each spectrum conversion component increases. In addition, the high reflectivity to visible light of the metal bank material can reduce the incidence of an overlarge beam angle of the spectrum conversion component. As a result, the optical blocking between adjacent spectrum conversion components can be increased, thereby reducing the optical cross-talk.

### BRIEF DESCRIPTION OF THE DRAWINGS

To illustrate more clearly the aforementioned and the other features, merits, and embodiments of the present disclosure, the description of the accompanying figures are as follows:

FIG. 1 is a locally cross-sectional view of a display light engine according to at least one embodiment of the present disclosure.

FIG. 2 is locally top view of a metal bank material according to at least one embodiment of the present disclosure.

FIG. 3A to FIG. 3D are locally cross-sectional views of a method for fabricating the display light engine according to at least one embodiment of the present disclosure.

FIG. 4A to FIG. 4B are locally cross-sectional views of a method for fabricating the display light engine according to another embodiment of the present disclosure.

FIG. 5 is a locally cross-sectional view of a display light engine according to another embodiment of the present disclosure.

FIG. 6 is a locally cross-sectional view of a display light engine according to another embodiment of the present disclosure.

FIG. 7A to FIG. 7D are locally cross-sectional views of a method for fabricating the display light engine according to another embodiment of the present disclosure.

FIG. 8 is a schematic view of an augmented reality display according to at least one embodiment of the present disclosure.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within ±30%, ±20%, ±10%, or ±5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

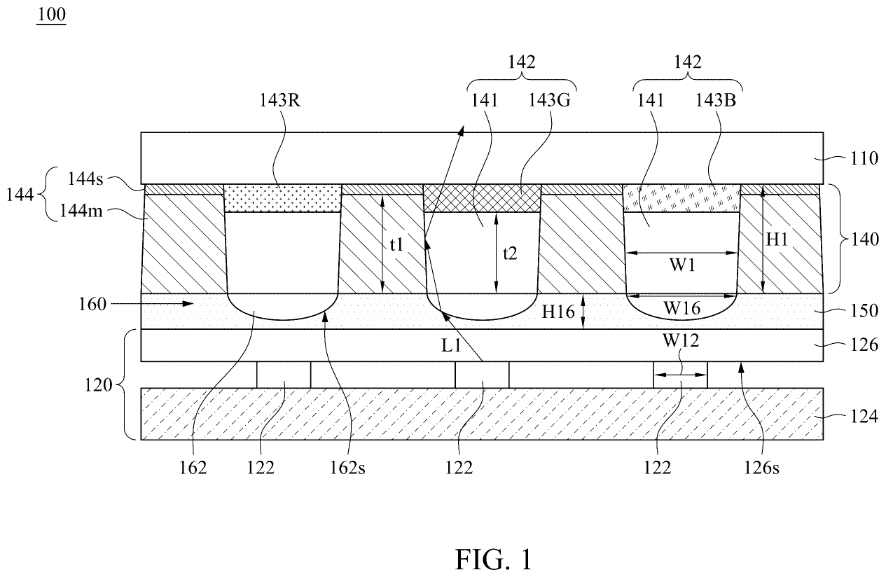

FIG. 1 is a locally cross-sectional view of a display light engine 100 according to at least one embodiment of the present disclosure. The display light engine 100 includes a light source module 120, a spectrum conversion array 140 and a lens array 160. The light source module 120 includes a plurality of light-emitting components 122, and these light-emitting components 122 are arranged on a pixel substrate 124 of the light source module 120 in an array and electrically connected to the pixel substrate 124. In the embodiment, the pixel substrate 124 may be a complementary metal oxide semiconductor (CMOS) substrate or a similar drive substrate of an electronic component. In addition, the light-emitting components 122 may include organic light emitting diodes (OLEDs), micro LEDs or similar solid-state light-emitting components.

For example, each of the light-emitting components 122 may be a white LED, but the disclosure is not limited to the embodiment. In other embodiments, the light-emitting components 122 may be red LEDs, blue LEDs or green LEDs. It is worth mentioning, the light source module 120 further includes a pixel define layer (PDL) which is not illustrated in the figures. The PDL is disposed on the pixel substrate 124 and separates each of the light-emitting components 122. The light source module 120 further includes an epitaxy substrate 126 which is located between the light-emitting components 122 and the lens array 160. A surface 126s of the epitaxy substrate 126 has a plurality of microstructures (not shown), and the light-emitting components 122 are disposed on the surface 126s. In the embodiment, the material of the epitaxy substrate 126 may include, such as, silicon dioxide.

The spectrum conversion array 140 is disposed on the light source module 120, while the light-emitting components 122 are configured to emit the light toward the spectrum conversion array 140. As shown in FIG. 1, the spectrum conversion array 140 includes a plurality of spectrum conversion components 142 which are spaced from each other, while the spectrum conversion components 142 are disposed on and align to the light-emitting components 122. Specifically, one spectrum conversion component 142 is disposed on one light-emitting component 122, and the spectrum conversion component 142 completely covers the light-emitting component 122 which aligns to it. In the embodiment, the aspect ratio of the spectrum conversion component 142 is between 3 and 5. That is, the height H1 of the spectrum conversion component 142 is from 3 to 5 times of the width W1 of the spectrum conversion component 142.

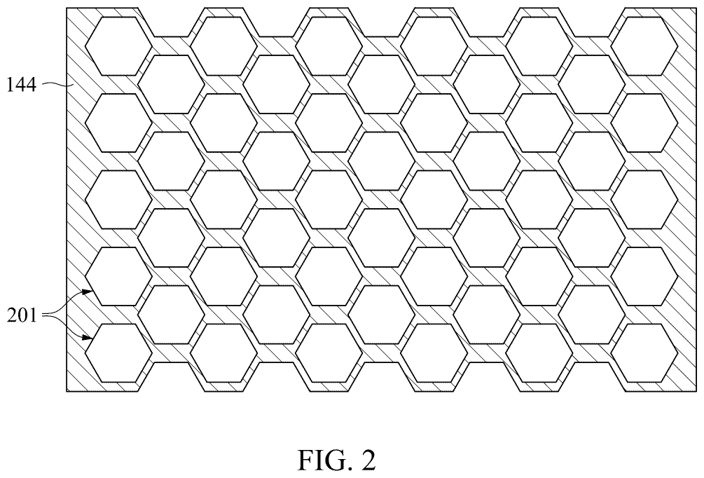

Furthermore, the spectrum conversion array 140 further includes a metal bank material 144. The metal bank material 144 is distributed between two spectrum conversion components 142 adjacent to each other and separates these spectrum conversion components 142. FIG. 2 illustrated a locally top view of the metal bank material 144. Referring to FIG. 1 and FIG. 2, the metal bank material 144 may be a reticular form, while each of the spectrum conversion components 142 is located inside a grid 201. In the embodiment, the grids 201 may be arranged in the form of a honeycomb, and two adjacent spectrum conversion components 142 are completely spaced from each other by the metal bank material 144. However, the disclosure is not limited to the embodiment. In other embodiments, the grids 201 may be arranged in other forms (e.g., in the form of a checkerboard).

Referring to FIG. 1, the lens array 160 is disposed between the spectrum conversion array 140 and the light source module 120 and includes a plurality of lenses 162 arranged in an array. The lenses 162 align to and disposed on the spectrum conversion components 142, respectively. Specifically, one lens 162 aligns to one spectrum conversion component 142 and also aligns to one light-emitting component 122.

It is worth mentioning, in the embodiment, the width W12 of each light-emitting component 122 is less than or equal to the width W16 of each lens 162. In addition, the ratio of the width W16 of each lens 162 and the width W12 of each light-emitting component 122 is between 1.0 and 1.5. For example, the width W12 of the light-emitting component 122 may be 2 μm, while the width W16 of the lens 162 may be 3 μm. However, the width W12 of the light-emitting component 122 and the width W16 of the lens 162 are not limited to this example.

In addition, the ratio of the height H16 and the width W16 of the lens 162 is between 0.5 and 2.0. For example, the width W16 of the lens 162 may be 3 μm, while the height H16 of the lens 162 may be 1.5 μm, but the height H16 of the lens 162 of the disclosure is not limited to this example. The materials of the lenses 162 may include epoxy resin, siloxane resin, polymer photoresist or similar materials.

As shown in FIG. 1, each spectrum conversion component 142 includes a translucent layer 141 and a light filter layer (e.g., the light filter layer 143R, the light filter layer 143G or the light filter layer 143B), while one translucent layer 141 covers one light-emitting component 122. The light filter layer (e.g., the light filter layer 143R, the light filter layer 143G or the light filter layer 143B) is disposed on the translucent layer 141, and the translucent layer 141 is located between this light filter layer and the light-emitting component 122. In the embodiment, the materials of the translucent layers 141 may include epoxy resin, siloxane resin, polymer photoresist or similar materials. In other words, the materials of the translucent layers 141 are similar to the materials of the lenses 162, but the disclosure is not limited to the embodiment. In other embodiments, the materials of the translucent layers 141 may be different from the material of the lenses 162.

The materials of the light filter layer 143R, the light filter layer 143G and the light filter layer 143B may include polymer resins or similar photoresist materials which include dyes or pigments. In the embodiment, the color of the light filter layer may be red, blue and green. Specifically, the light filter layer 143R shown in FIG. 1 may be a red light filter layer. The light filter layer 143B may be a blue light filter layer, while the light filter layer 143G may be a green light filter layer. However, the disclosure is not limited to the embodiment. In other embodiments, the light filter layers may include any color other than the aforementioned three colors, such as cyan, magenta or yellow. Moreover, the light filter layers may include more than three colors. For example, the light filter layers may include four colors, such as red, blue, green and yellow.

Referring to FIG. 1, the metal bank material 144 includes a seed layer 144s and a metal layer 144m. The metal layer 144m is disposed on the seed layer 144s, while the metal layer 144m is located between the seed layer 144s and the lens array 160. The material of the seed layer 144s may include metals or alloys with lower reflectivity to visible light, such as, tungsten or nickel (e.g., tungsten-nickel alloys). The material of the metal layer 144m may include metals or alloys with higher reflectivity to visible light, such as, silver or aluminum.

After the light-emitting component 122 emits a light ray L1 toward the spectrum conversion array 140, the light ray L1 passes through the lens array 160 and enters the spectrum conversion component 142. Thus, the light path of the light ray L1 may be restricted within the spectrum conversion component 142 by the reflection of the metal bank material 144 since the metal bank material 144 (i.e., the seed layer 144s and the metal layer 144m) includes metallic materials with high reflectivity to visible light. As a result, the quantity of light from the spectrum conversion components 142 increases.

In the embodiment, the thickness of the metal layer 144m in the metal bank material 144 may be between 6 μm and 10 μm, while the thickness of the seed layer 144s may be less than 1 μm. Furthermore, the thickness of the translucent layer 141 in the spectrum conversion component 142 may be between 6 μm and 10 μm, while the thickness of the light filter layer (e.g., the light filter layer 143R, the light filter layer 143G or the light filter layer 143B) may be between 1 μm and 2 μm. It is worth mentioning, the thickness t1 of the metal layer 144m is larger than the thickness t2 of the translucent layer 141 in this embodiment. Since the metal layer 144m blocks off the side surface of the translucent layer 141 completely, and due to the reflectivity of the metal bank material 144 to visible light, it is advantage for increasing the probability of the light ray L1 to enter the light filter layer (e.g., the light filter layer 143R, the light filter layer 143G or the light filter layer 143B). Thus, the light rays L1 emitted by adjacent spectrum conversion components 142 are prevented from affecting by each other, so that the optical cross-talk is reduced.

As shown in FIG. 1, the display light engine 100 further includes a substrate 110. The substrate 110 is disposed on the spectrum conversion array 140, while the spectrum conversion array 140 is located between the substrate 110 and the lens array 160. The substrate 110 may be a transparent substrate, such as, a glass substrate or a transparent plastic substrate. In addition, the display light engine 100 further includes a translucent medium 150. The translucent medium 150 is located between the lens array 160 and the light source module 120 and covers the surfaces 162s of the lenses 162. It is worth mentioning, the refractive index of the translucent medium 150 is less than the refractive index of the lens 162. For example, in the embodiment, the lenses 162 may include the epoxy resin whose refractive index is 1.3, while the translucent medium 150 may include the medium whose refractive index is less than 1.3. Furthermore, in other embodiments, the translucent medium 150 may be replaced with air, that is, the translucent medium 150 may substantially be the air whose refractive index is less than 1.3.

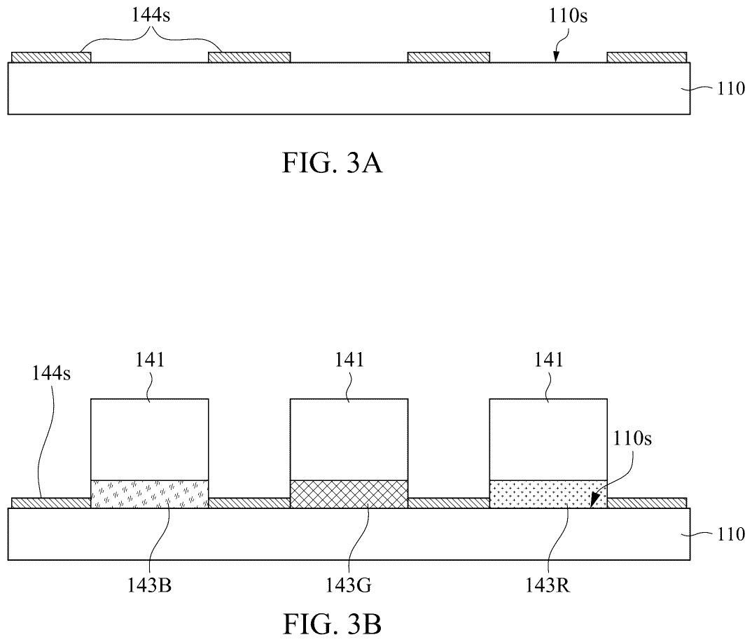

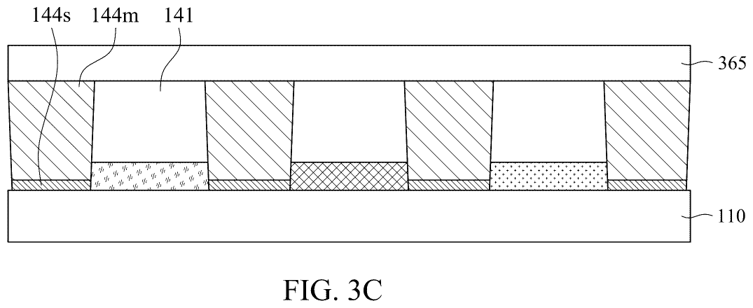

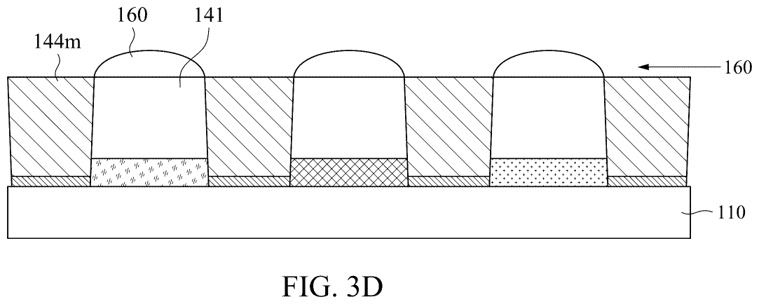

The method for fabrication of the display light engine 100 is described by sequent steps illustrated in FIG. 3A to FIG. 3D. Referring to FIG. 3A, the substrate 110 is provided, and an initial seed layer (not shown) is deposited on the surface 110s of the substrate 110 by sputtering. After the initial seed layer is deposited, the initial seed layer is patterned by methods, such as, lithography and etching, so as to form the seed layer 144s. In the embodiment, the seed layer 144s may be a reticular form, and the reticular pattern is identical to the pattern of the metal bank material 144 in FIG. 2.

Referring to FIG. 3B, the plurality of translucent layers 141 are disposed on the substrate 110 after the seed layer 144s is formed. These translucent layers 141 are distributed over the surface 110s where is uncovered by the seed layer 144s. Next, as shown in FIG. 3C, the metal layer 144m is deposited on the seed layer 144s by electroplating, while the metal layer 144m is distributed in the spacing between each of the translucent layers 141.

It is worth mentioning, in the embodiment, the light filter layer 143R, the light filter layer 143B and the light filter layer 143G may be disposed on the substrate 110 before the translucent layers 141 are disposed, and then the translucent layers 141 are disposed on the light filter layer 143R, the light filter layer 143B and the light filter layer 143G, respectively. However, the disclosure is not limited to the embodiment. In other embodiments, the light filter layer 143R, the light filter layer 143B and the light filter layer 143G may be disposed on the substrate 110 after the translucent layers 141 are disposed.

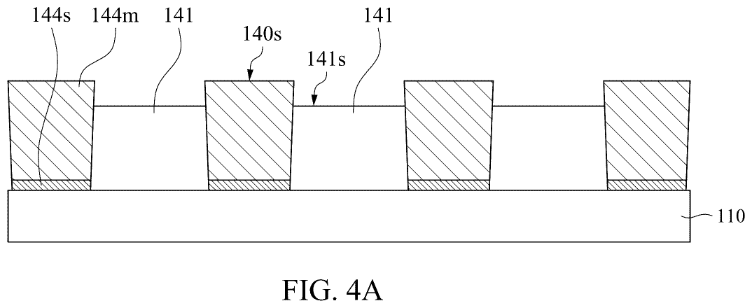

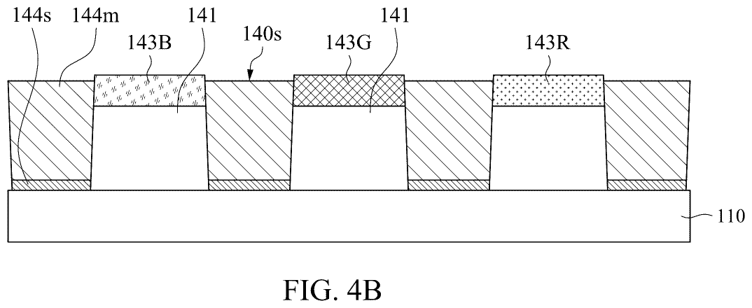

Specifically, referring to FIG. 4A to FIG. 4B according to another embodiment of the present disclosure, a part of the metal bank material 144 may be removed by dry etching after the metal layer 144m is deposited. Thus, the metal layer 144m is retained (i.e., the metal layer 144m is not etched), so that the surface 141s of the translucent layers 141 is recessed to the surface 140s of the metal layer 144m. The aforementioned dry etching may refer to etching the translucent layers 141 by oxygen plasma. Next, as shown in FIG. 4B, the light filter layer 143R, the light filter layer 143B and the light filter layer 143G are disposed on the surface 141s of the translucent layers 141, respectively. In the embodiment, the surface of the light filter layer 143R (not denoted), the surface of the light filter layer 143B (not denoted) and the surface of the light filter layer 143G (not denoted) may protrude from the surface 140s of the metal layer 144m.

Referring to the embodiment of FIG. 3C, an over coating (OC) 365 is formed on the metal layer 144m and the translucent layers 141 by spin coating after the metal layer 144m is deposited. The over coating 365 covers the metal layer 144m and the translucent layers 141, and this over coating 365 may include, such as, epoxy resin, siloxane resin, polymer photoresist or similar materials. Next, referring to FIG. 3D, the over coating 365 is patterned by etching, so as to form the lens array 160.

Specifically, a photoresist layer (not shown) may be disposed on the over coating 365 and is patterned by lithography, so that a micro-lens array (MLA) is formed. Next, the micro-lens array and a part of the over coating 365 is removed by dry etching, and the plasma materials of the aforementioned dry etching may include SF6. Accordingly, the structure of the micro-lens array is transferring-printed on the over coating 365, so as to form the lens array 160 whose structure is identical to the structure of the micro-lens array. In other words, the structure of the micro-lens array may be replicated on the over coating 365 in a scale of 1:1.

After the lens array 160 is formed, the light source module 120 shown in FIG. 1 is provided, and the light source module 120 is disposed on the lens array 160. The light-emitting components 122 of the light source module 120 are located between the lens array 160 and the pixel substrate 124 of the light source module 120, while the light-emitting components 122 are disposed on the lenses 162 of the lens array 160 one-on-one.

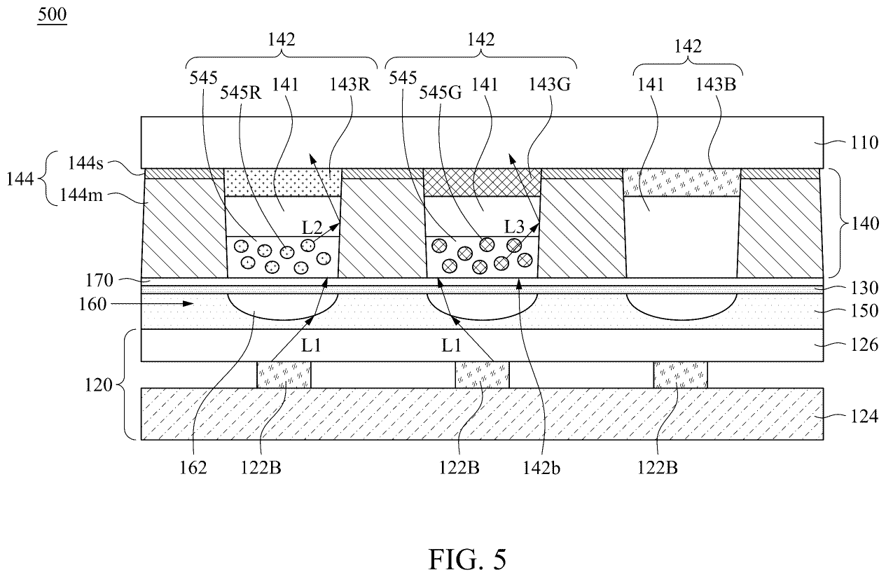

FIG. 5 is a locally cross-sectional view of a display light engine 500 according to another embodiment of the present disclosure. The structure of the display light engine 500 is similar to the display light engine 100. The difference between the display light engine 100 and the display light engine 500 is that a part of the spectrum conversion components 142 in the display light engine 500 further include a wavelength conversion layer 545. The wavelength conversion layer 545 is disposed on the translucent layer 141 and covers one of the light-emitting components 122B. As shown in FIG. 5, the translucent layers 141 of a part of the spectrum conversion components 142 are located between the light filter layer (i.e., the light filter layer 143R and the light filter layer 143G) and the wavelength conversion layers 545. In the embodiment, the thickness of a part of the translucent layers 141 (i.e., the translucent layer 141 where the wavelength conversion layer 545 is disposed) is between 3 μm and 5 μm. Each thickness of the light filter layer 143R, the light filter layer 143B and the light filter layer 143G is between 1 μm and 2 μm, while the thickness of the wavelength conversion layer 545 is between 1 μm and 5 μm. However, the thickness of each layer of the spectrum conversion component 142 is not limited to the aforementioned embodiment.

The wavelength conversion layer 545 may include, such as, quantum dots, fluorescent pigments or similar materials. As a result, after the light ray L1 enters the wavelength conversion layer 545, the wavelength conversion layer 545 may emit a light ray with different wavelengths from the light ray L1. In the embodiment, the wavelength conversion layer 545 may include red quantum dots 545R or green quantum dots 545G, while the light-emitting component 122B may emit the light ray L1 with wavelengths between 400 nm and 495 nm (i.e., within the wavelengths of blue light).

Specifically, one of the wavelength conversion layers 545 includes the red quantum dots 545R, while the other wavelength conversion layer 545 includes the green quantum dots 545G. Thus, one of the wavelength conversion layers 545 may emit the light ray L2 with wavelengths between 620 nm and 750 nm (i.e., within the wavelengths of red light), while the other wavelength conversion layer 545 may emit the light ray L3 with wavelengths between 495 nm and 570 nm (i.e., within the wavelengths of green light). Although the light ray (e.g., the light ray L2 or the light ray L3) emitted by the wavelength conversion layer 545 is scattered light, the light paths of the light ray L2 and the light ray L3 may be restricted within the spectrum conversion components 142 due to the high reflectivity of the metal bank material 144 (including the seed layer 144s and the metal layer 144m) to visible light.

In the embodiment, the display light engine 100 further includes a distributed Bragg reflector (DBR) 130 and a flattened layer 170. The distributed

Bragg reflector 130 is disposed between the spectrum conversion array 140 and the lens array 160, while the flattened layer 170 is disposed between the distributed Bragg reflector 130 and the spectrum conversion array 140. In the embodiment, the distributed Bragg reflector 130 is a yellow light reflector and is configured to reduce the proportion of light emitted by the wavelength conversion layers 545 exiting from the bottom surface 142b of the spectrum conversion component 142. In addition, since the bottom surface 142b of the spectrum conversion component 142 is not flush with the surface 140s of the metal layer 144m, the flattened layer 170 is configured to planarize the interface between the spectrum conversion array 140 and the lens array 160. The flattened layer 170 may include, such as, epoxy resin, siloxane resin, polymer photoresist or similar materials.

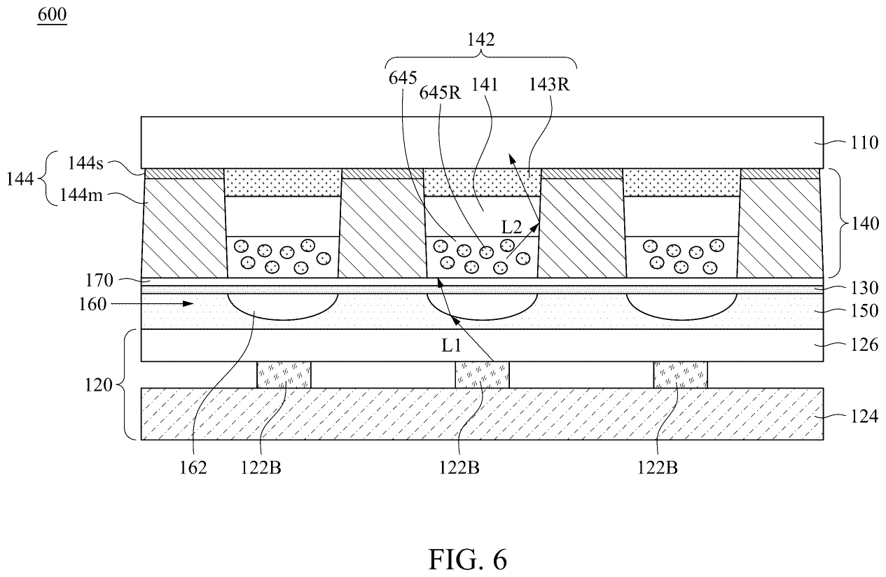

FIG. 6 is a locally cross-sectional view of a display light engine 600 according to another embodiment of the present disclosure. The structure of the display light engine 600 is similar to the display light engine 500. The difference between the display light engine 500 and the display light engine 600 is that each of the spectrum conversion arrays 140 in the display light engine 600 includes a wavelength conversion layer 645. The wavelength conversion layer 645 is disposed on the translucent layer 141 and covers one of the light-emitting components 122. As shown in FIG. 6, the translucent layer 141 is located between the light filter layer 143R and the wavelength conversion layer 645.

It is worth mentioning, in the embodiment, the wavelength conversion layer 645 includes the quantum dot materials in the same color, so that the display light engine 600 may emit red light, green light or blue light. Take the display light engine 600 which emits red light for example, each of the wavelength conversion layers 645 includes red quantum dots 645R. Further, all of the light filter layers in this embodiment are red filter layers 143R. In practical applications, since the display light engine 600 may emit monochromatic light, three kinds of display light engines 600 that emit red light, blue light, and green light are assembled by a trichronic prism assembly, so as to project full color images.

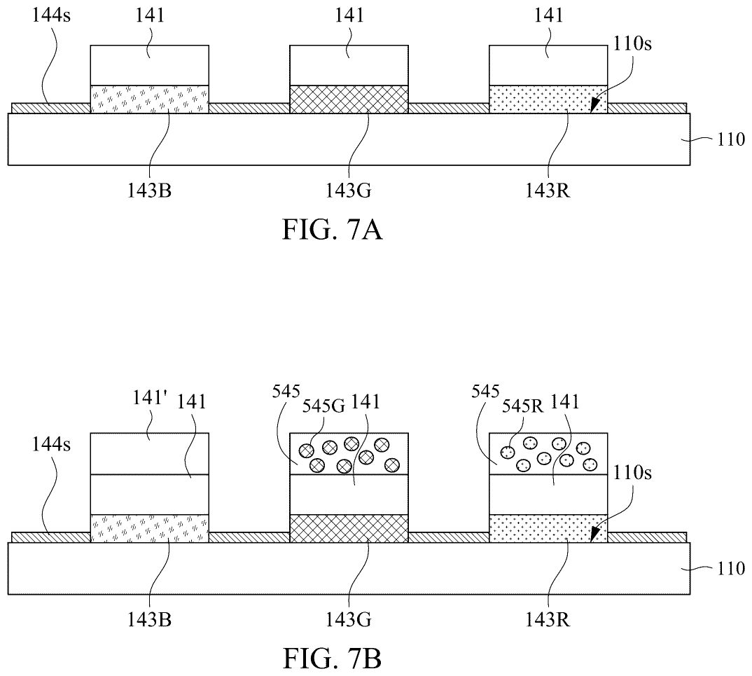

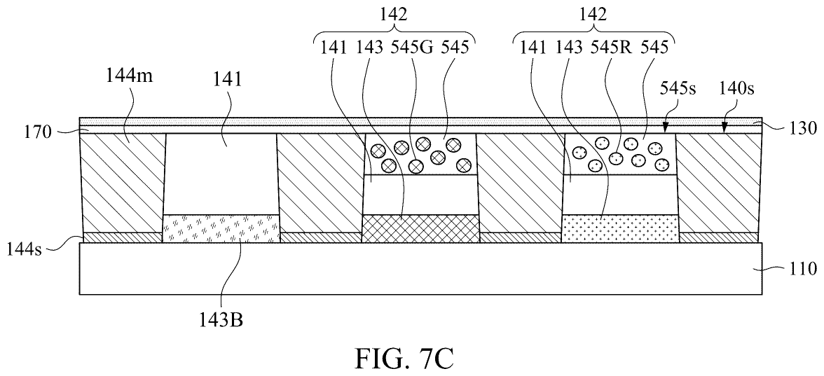

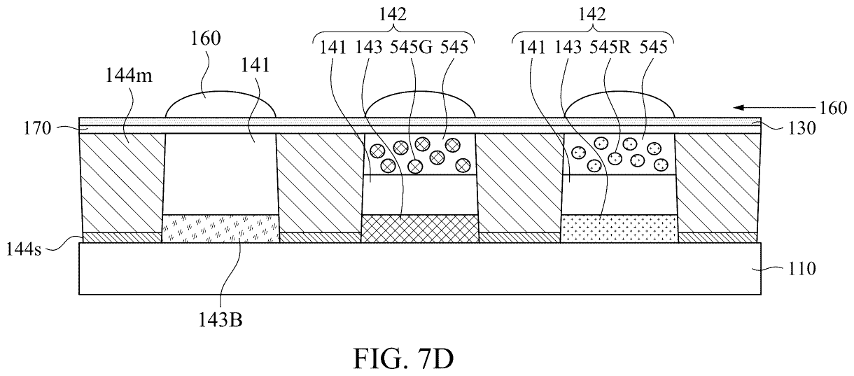

The method for fabrication of the display light engine 500 is described by sequent steps illustrated in FIG. 7A to FIG. 7D. Referring to FIG. 7A, the substrate 110 is provided, and an initial seed layer (not shown) is deposited on the surface 110s of the substrate 110 by sputtering. After the initial seed layer is deposited, the initial seed layer is patterned by methods, such as, lithography and etching, so as to form the seed layer 144s. The plurality of light filter layers (i.e., the light filter layer 143R, the light filter layer 143B and the light filter layer 143G) are disposed on the substrate 110 after the seed layer 144s is formed. These light filter layers are distributed over the surface 110s where is uncovered by the seed layer 144s. Next, the translucent layers 141 are disposed on the light filter layer 143R, the light filter layer 143B and the light filter layer 143G, respectively.

Next, referring to FIG. 7B, the wavelength conversion layers 545 are formed on a part of the translucent layers 141. Specifically, the wavelength conversion layer 545 which includes the red quantum dots 545R and the wavelength conversion layer 545 which includes the green quantum dots 545G are separately formed on two of the translucent layers 141 in FIG. 7B (i.e., the translucent layers 141 in the middle and on the right of FIG. 7B). Furthermore, the translucent layer 141′ is formed on the other one of the translucent layers 141 in FIG. 7B (i.e., the translucent layer 141 on the left of FIG. 7B), and the translucent layer 141′ and the translucent layers 141 include identical materials. In other words, the translucent layer 141′ is the extension of the translucent layer 141 substantially.

Referring to FIG. 7C, the metal layer 144m may be deposited on the seed layer 144s by electroplating after the wavelength conversion layers 545 are formed. The metal layer 144m is distributed in the spacing between each of the translucent layers 141. It is worth mentioning, the surface 140s of the metal layer 144m is recessed to the surface 545s of the wavelength conversion layer 545, while the distance between the surface 140s and the surface 545s is less than 0.5 μm.

After the metal layer 144m is deposited, the flattened layer 170 is formed on the surface 140s of the metal layer 144m and the surface 545s of the wavelength conversion layers 545. Next, the distributed Bragg reflector 130 is disposed on the flattened layer 170. Referring to FIG. 7D, the lens array 160 is formed on the distributed Bragg reflector 130 after the flattened layer 170 and the distributed Bragg reflector 130 are disposed. The methods of forming the lens array 160 may include forming a covering film (not shown) on the metal layer 144m and the translucent layers 141 by spin coating or spray developing. Next, the covering film may be patterned by reflowing after lithography, so as to form the lens array 160. In addition, if the covering film is a non-photosensitive material with high refractive index, the covering film may be patterned by dry etching through hard masks, so that to form the lens array 160.

After the lens array 160 is formed, the light source module 120 shown in FIG. 5 is provided and disposed on the lens array 160. The light-emitting components 122 of the light source module 120 are located between the lens array 160 and the pixel substrate 124 of the light source module 120, while the light-emitting components 122B are disposed on and align to the lenses 162 of the lens array 160 one-on-one.

It is worth mentioning, each of the display light engine 100, the display light engine 500 and the display light engine 600 may further include a collimating lens, even though the collimating lens is not illustrated in the figures. The collimating lens is disposed on the spectrum conversion array 140, while the spectrum conversion array 140 is located between the collimating lens and the light source module 120. The beam angle of the light ray L1 emitted by the light source module 120 and passing through the spectrum conversion array 140 is between 45° and 60°, while the beam angle which passes through the collimating lens is less than or equal to 30°.

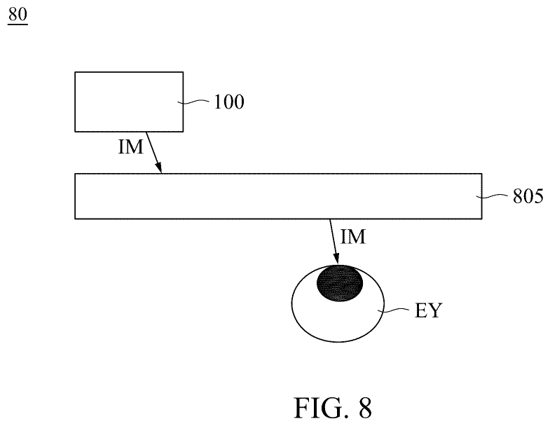

Referring to FIG. 1 and FIG. 8, an augmented reality display 80 of the embodiment of the disclosure includes the display light engine 100 (the display light engine 500 or the display light engine 600) and a light guide module 805. The light guide module 805 may include optical waveguide components. As shown in FIG. 8, the augmented reality display 80 may be worn in front of the user's eyes EY (i.e., wearer's eyes), and the display light engine 100 is configured to emit an image light ray IM. The light guide module 805 is configured to receive the image light ray IM emitted by the display light engine 100 and to focus and transmit the image light ray IM toward wearer's eyes. The lenses 162 of the display light engine 100 are configured to refract the light ray L1 emitted by the light-emitting components 122 aligning to the lenses 162, so that the light ray L1 enters the spectrum conversion component 142 aligning to the light-emitting components 122.

In conclusion, the metal bank material is disposed between the spectrum conversion components. Since the metals included in the metal bank material are with high reflectivity to visible light, the light path of the light ray is restricted within the each spectrum conversion component. Therefore, the quantity of light of each spectrum conversion component increases. In addition, the high reflectivity to visible light of the metal bank material can reduce the incidence of an overlarge beam angle of the spectrum conversion component. As a result, the optical blocking between adjacent spectrum conversion components can be increased, thereby reducing the optical cross-talk.

Although the present disclosure has been described in considerable detail with reference to certain embodiments thereof, other embodiments are possible. Therefore, the spirit and scope of the appended claims should not be limited to the description of the embodiments contained herein.

What is claimed is:

1. A display light engine, comprising:
a light source module comprising a plurality of light-emitting components, wherein the plurality of light-emitting components are arranged in an array;
a spectrum conversion array disposed on the light source module, and the plurality of light-emitting components are configured to emit light toward the spectrum conversion array, wherein the spectrum conversion array comprises:
a plurality of spectrum conversion components spaced from each other, and the plurality of spectrum conversion components are disposed on and align to the plurality of light-emitting components;
a metal bank material distributed between two of the plurality of spectrum conversion components adjacent to each other and separating the plurality of spectrum conversion components from each other; and
a lens array disposed between the spectrum conversion array and the light source module and comprising a plurality of lenses arranged in an array, wherein the plurality of lenses are disposed on and align to the plurality of spectrum conversion components respectively.

2. The display light engine of claim 1, wherein each of the plurality of spectrum conversion components comprises:
a translucent layer covering one of the plurality of light-emitting components; and
a light filter layer disposed on the translucent layer, wherein the translucent layer is located between the light filter layer and the plurality of light-emitting components.

3. The display light engine of claim 2, wherein a part of the plurality of spectrum conversion components further comprises:
a wavelength conversion layer disposed on the translucent layer and covering one of the plurality of light-emitting components, wherein the translucent layer is located between the light filter layer and the wavelength conversion layer.

4. The display light engine of claim 3, wherein the wavelength conversion layer comprises a material selected from the group consisting of a red quantum dot material and a green quantum dot material.

5. The display light engine of claim 2, wherein each of the plurality of spectrum conversion components further comprises:
a wavelength conversion layer disposed on the translucent layer and covering one of the plurality of light-emitting components, wherein the translucent layer is located between the light filter layer and the wavelength conversion layer.

6. The display light engine of claim 5, wherein the wavelength conversion layers of the plurality of spectrum conversion components comprise quantum dot materials in the same color.

7. The display light engine of claim 2, wherein the metal bank material comprises:
a seed layer; and
a metal layer disposed on the seed layer, and the metal layer is located between the seed layer and the lens array.

8. The display light engine of claim 7, wherein a thickness of the metal layer is larger than a thickness of the translucent layer.

9. The display light engine of claim 7, wherein a material of the metal layer comprises silver.

10. The display light engine of claim 7, wherein a material of the seed layer is selected from the group consisting of copper and gold.

11. The display light engine of claim 1, further comprising:
a collimating lens disposed on the spectrum conversion array, and the spectrum conversion array is located between the collimating lens and the light source module, wherein a beam angle of a light ray emitted by the light source module and passing through the spectrum conversion array is between 45° and 60°, and the beam angle passing through the collimating lens is less than or equal to 30°.

12. The display light engine of claim 1, wherein a width of each of the plurality of light-emitting components is less than or equal to a width of each of the plurality of lenses, and a ratio of the width of each of the plurality of lens and the width of the plurality of light-emitting components is between 1.0 and 1.5.

13. The display light engine of claim 1, further comprising:
a distributed Bragg reflector disposed between the spectrum conversion array and the lens array.

14. The display light engine of claim 1, further comprising:
a translucent medium disposed between the lens array and the light source module and covering a surface of the plurality of lenses, wherein a refractive index of the translucent medium is less than 1.3.

15. An augmented reality display, comprising:
a display light engine, comprising:
a light source module comprising a plurality of light-emitting components, wherein the plurality of light-emitting components are arranged in an array;
a spectrum conversion array disposed on the light source module, and the plurality of light-emitting components are configured to emit light toward the spectrum conversion array, wherein the spectrum conversion array comprises:
a plurality of spectrum conversion components spaced from each other, and the plurality of spectrum conversion components are disposed on and align to the plurality of light-emitting components;
a metal bank material distributed between two of the plurality of spectrum conversion components adjacent to each other and separating the plurality of spectrum conversion components from each other; and
a lens array disposed between the spectrum conversion array and the light source module and comprising a plurality of lenses arranged in an array, wherein the plurality of lenses are disposed on and align to the plurality of spectrum conversion components respectively, wherein the display light engine is configured to emit an image light ray,
wherein the plurality of lens of the display light engine are configured to refract a light ray emitted by the plurality of light-emitting components aligning to the plurality of lens respectively, so that the light ray enters the plurality of spectrum conversion components align to the plurality of light-emitting components; and
a light guide module configured to receive the image light ray emitted by the display light engine and to focus and transmit the image light ray toward wearer's eyes.
